(19) United States
(12) Patent Application Publication
(10) Pub. No.: US 2026/0223746 A1
(43) Pub. Date: Jul. 30, 2026

(54) SEMICONDUCTOR DEVICE, LSI MODULE, AND SWITCHING POWER SUPPLY DEVICE

(71) Applicant: ROHM CO., LTD., Kyoto (JP)

(72) Inventors: Takumi FUJIMAKI, Kyoto (JP); Satoru NATE, Kyoto (JP)

(21) Appl. No.: 19/461,040

(22) Filed: Jan. 27, 2026

(30) Foreign Application Priority Data
Jan. 29, 2025 (JP) 2025-012855

(51) Int. Cl. H10W 90/10; H10D 80/20; H10D 80/30; H10W 40/20; H10W 70/40; H10W 90/00

(52) U.S. Cl. CPC H10W 90/10; H10D 80/251; H10D 80/30; H10W 40/242; H10W 70/417; H10W 70/461; H10W 90/736; H10W 90/753; H10W 90/756; H10W 90/811

(57) ABSTRACT

A semiconductor device includes a GaN power device of which the gate breakdown voltage has a positive temperature response, a voltage supplying portion that supplies, when the GaN power device is turned on, a voltage at a high level with a positive temperature response to the gate of the GaN power device, and a heat conducting portion that conducts heat between the GaN power device and the voltage supplying portion.

### CROSS REFERENCE TO RELATED APPLICATIONS

This application is based on Japanese Patent Application No. 2025-12855 filed on Jan. 29, 2025, the contents of which are hereby incorporated by reference.

### BACKGROUND OF THE INVENTION

### 1. Technical Field

The present invention relates to a semiconductor device, an LSI module, and a switching power supply device.

### 2. Description of Related Art

In power electronics, as a switching device for use in a switching circuit, a transition is underway from known Si devices to GaN devices.

One example of the conventional art related to the above is seen in Patent Literature 1 (JP2024-39516A).

### BRIEF DESCRIPTION OF THE DRAWINGS

FIG. 1 is a schematic perspective view of an LSI package including a semiconductor device.

FIG. 2 is a schematic plan view of the LSI package.

FIG. 3 is a schematic side view of the LSI package.

FIG. 4 is a schematic view of the LSI package including the semiconductor device.

FIG. 5 is a graph showing, for a GaN power device, the temperature characteristics of the gate breakdown voltage and the gate voltage.

FIG. 6 is a graph showing the temperature characteristics of the on-resistance of the GaN power device.

FIG. 7 is a schematic layout diagram showing a first and a second semiconductor chip in a semiconductor device.

FIG. 8 is a schematic circuit diagram showing one example of the configuration a switching power supply device using the semiconductor device.

FIG. 9 is a schematic configuration diagram of a motor device.

### DETAILED DESCRIPTION

Now, an example of an embodiment of the present disclosure will be described in detail with reference to the accompanying drawings. In the diagrams referred to in the course, the same reference signs represent the same parts and, for the same parts, basically no overlapping description will be repeated.

Any “connection” mentioned with respect to a plurality of parts that form any circuit element, wire, or circuit covers not only mechanical connection but also electrical connection. In other words, it covers a state where electricity passes among them. That is, “to connect” can mean “to electrically connect.”

A switch can be in an on state or an off state. When a switch is in an on state, it conducts across its opposite ends. On the other hand, when a switch is in an off state, it does not conduct across its opposite ends. In the following description, being in an on state or an off state is occasionally referred to simply as being on or off.

As one example of a switching device, a MOS (metal-oxide-semiconductor) field-effect transistor can be used. The MOS field-effect transistor is a transistor having a gate structure composed of at least three layers, namely “a layer of a conductor or a semiconductor with a small resistance, such as a polysilicon,” “an insulating layer,” and “a semiconductor layer of a P-channel type, a N-channel type, or an intrinsic type.” That is, the gate structure of the MOS field-effect transistor is not limited to the three-layered configuration of metal, an oxide, and a semiconductor.

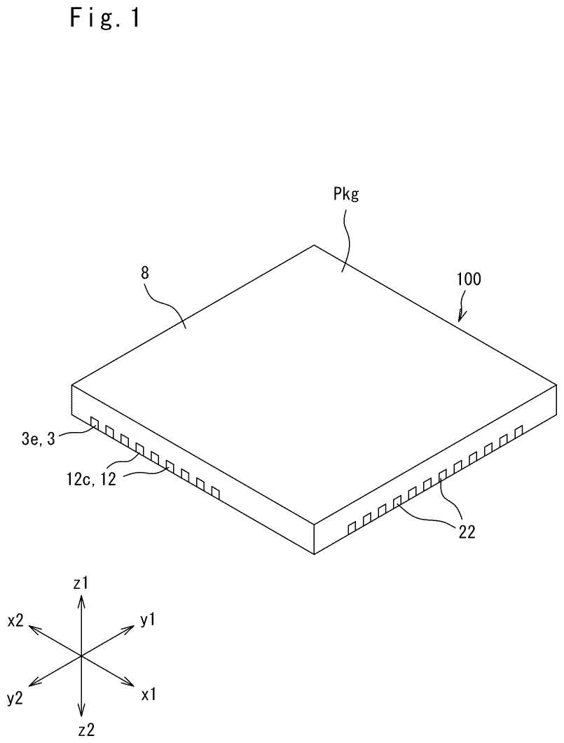

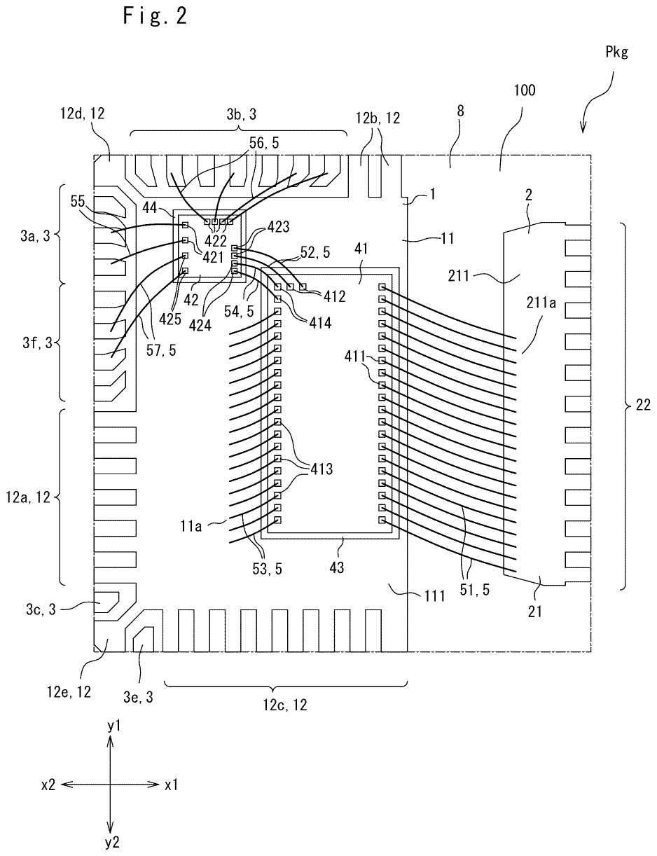

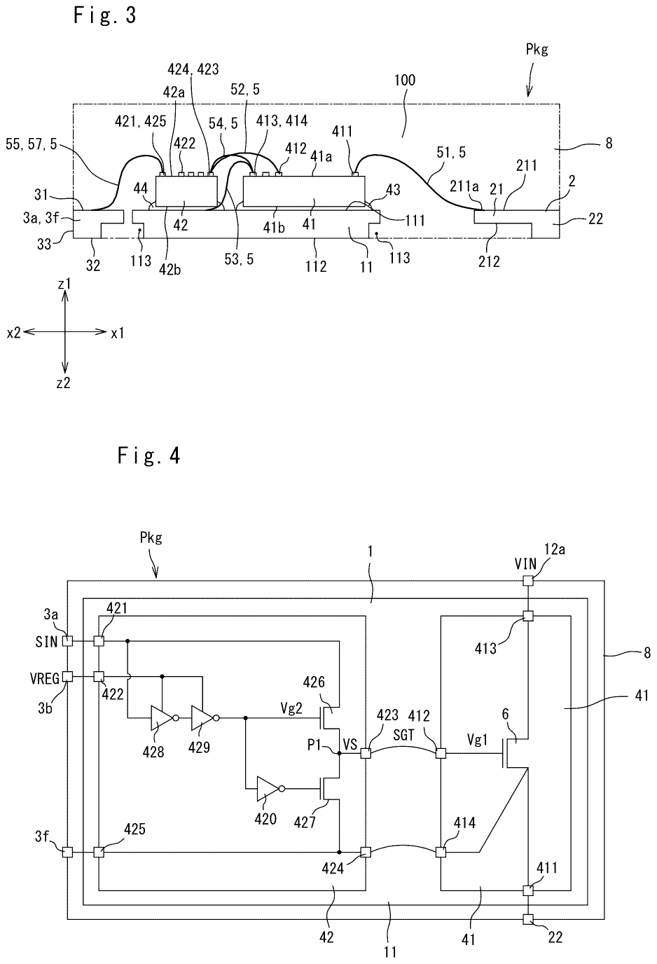

A description will be given of an LSI (large scale integration) package Pkg including a semiconductor device 100 according to the present disclosure, and of the semiconductor device 100, with reference to the accompanying drawings. FIG. 1 is a schematic perspective view of the LSI package Pkg including the semiconductor device 100. FIG. 2 is a schematic plan view of the LSI package. FIG. 3 is a schematic side view of the LSI package Pkg. FIG. 4 is a schematic view of the LSI package Pkg including the semiconductor device 100. Note that, in the semiconductor device 100 shown in FIGS. 2 and 3, a sealing resin 8 is assumed to be transparent and is indicated by dash-dotted lines.

As shown in FIGS. 1 and 2, the semiconductor device 100 includes a first lead a second lead 2, a plurality of third leads 3, a first semiconductor chip 41, a second semiconductor chip 42, a plurality of wires 5, and a sealing resin 8. The semiconductor device 100 amplifies an input signal fed to it from outside. The semiconductor device 100 has a QFN (Quad Flat No-lead) package. The semiconductor device 100 can have any package other than a QFN package.

The semiconductor device 100 is in the shape of a rectangular as seen from above. Note that, in the following description, with reference to the state in FIG. 1, a first direction, a second direction, and a third direction are defined. Specifically, the thickness direction of the semiconductor device 100 is the third direction z. The direction orthogonal to the third direction z and running along one edge of the semiconductor device 100 is the first direction x. The direction orthogonal to the third and first directions z and x is the second direction y. Along the third direction z, one side (upward in FIGS. 1 and 3) is the first side z1 and the other side (downward in FIGS. 1 and 3) is the second side z2. Along the first direction x, one side (rightward in FIGS. 1 and 2) is the first side x1 and the other side (leftward in FIGS. 1 and 2) is the second side x2. Along the second direction y, one side (upward in FIG. 2) is the first side y1 and the other side (downward in FIG. 2) is the second side y2. Note that the shape and dimensions of the semiconductor device 100 are merely examples and may vary in practice.

The first, the second, and the plurality of third leads 1, 2, and 3 (hereinafter, occasionally referred to as leads 1 to 3 collectively) are members constituting conducting paths between the first and second semiconductor chips 41 and 42 and a wiring substrate on which the semiconductor device 100 is mounted. The leads 1 to 3 are formed of an electrically conductive material, such as metal. Note that some of the plurality of third leads 3 do not conduct to either the first or second semiconductor chip 41 or 42.

As will be described later, on the first lead 1, the first and second semiconductor chips 41 and 42 are mounted. The first lead 1 is a heat conducting portion that conducts heat between the first and second semiconductor chips 41 and 42. Thus, preferably, at least the first lead 1 is formed of a material having higher heat conductivity than either of the first and second semiconductor chips 41 and 42. For example, the first, second, and third leads 1, 2, and 3 can be formed of the same material or different materials. The semiconductor device 100 according to the present disclosure has the leads 1 to 3 formed of the same material, and suitable as such materials are Cu and Ni or alloys of these two.

As shown in FIG. 2, the first lead 1 is in the form of a flat plate extending alon the first and second directions x and y and stretches across the entire dimension of the semiconductor device 100 along the second direction y. The first lead 1 is disposed displaced toward the second side x2 with respect to the middle along the first direction x. The second lead 2 is disposed at the first side x1 along the first direction x on the semiconductor device 100, in a middle part of it along the second direction. The plurality of third leads 3 are arrayed at intervals along sides of the semiconductor device 100 in the rectangular shape as seen from above. That is, the plurality of third leads 3 are disposed away from each other and also away from the first and second leads 1 and 2. Note that, as seen from the third direction z, the first lead 1 is larger than the second lead 2 and the second lead 2 is larger than each third lead 3.

The first lead 1 includes a die pad 11 and a plurality of terminals 12. As shown in FIG. 2, as seen from the third direction z, the die pad 11 has the shape of a rectangular plate with its longitudinal direction aligned with the second direction y. The die pad 11 is displaced toward the second side x2 along the first direction x of the semiconductor device 100 and is disposed in a middle part of it along the second direction y. Of the die pad 11, a face at the first side z1 and a face at the second side z2 along the third direction z are defined as a main face 111 and a back face 112, respectively.

The main and back faces 111 and 112 face away from each other along the third direction z. The main face 111 faces the first side z1 along the third direction z. On the main face 111, the first and second semiconductor chips 41 and 42 are mounted.

The back face 112 of the die pad 11 has, formed as a part of it, a back face depressed part 113 that is depressed toward the first side z1 along the third direction z. As shown in FIG. 3, the back face depressed part 113 is disposed along the circumference of the back face 112. The back face depressed part 113 is not exposed out of the sealing resin 8 and is covered by the sealing resin 8. This prevents the first lead 1 from coming off the sealing resin 8. Note that the shape of the die pad 11 is not limited to as described above. For example, the die pad 11 do es not necessarily have the back face depressed part 113.

As shown in FIG. 2, the main face 111 of the die pad 11 has a bonded region 11a. The bonded region 11a is located in a part of the first semiconductor chip 41 toward the second side x2 along the first direction x and is a region to which the wires 5 (third wires 53, which will be described later) are bonded. The bonded region 11a can be subjected to plating. The plated layer formed by plating is formed of, for example, metal such as Ag. The plated layer enhances the bonding strength of the third wires 53 and also protects the first lead 1 from impact resulting from wire bonding of the third wires 53.

When the semiconductor device 100 is mounted on the wiring substrate, the plurality of terminals 12 are bonded to the wiring substrate. The terminals 12 are coupled to the die pad 11 to be integrated with it. The plurality of terminals 12 include six terminals 12a, two terminals 12b, eight terminals 12c, and terminals 12d and 12e. The six terminals 12a are coupled to an end part of the die pad 11 toward the second side x2 along the first direction x, displaced toward the second side y2 along the second direction y. The terminals 12a are arrayed along the second direction y.

The two terminals 12b are arrayed along the first direction x in an end part of the die pad 11 toward the first side y1 along the second direction y, displaced toward the second side x2 along the first direction x. The eight terminals 12c are arrayed along the first direction x in an end part of the die pad 11 toward the second side y2 along the second direction y. The terminal 12d is coupled to a corner of the die pad 11 toward the second side x2 along the first direction x, toward the first side y1 along the second direction y. The terminal 12e is coupled to a corner of the die pad 11 toward the second side x2 along the first direction x, toward the second side y2 along the second direction y. Note that the shape, arrangement position, and number of terminals 12 are not limited to as described above.

The second lead 2 is disposed away from the first lead 1 toward the first side along the first direction x. The die pad 11 of the first lead 1 and the second lead 2 are disposed side by side along the first direction x. The second lead 2 is electrically connected to the first semiconductor chip 41 via the plurality of wires 5 (a plurality of fourth wires 54, which will be described later). The second lead 2 has a pad portion 21 and a plurality of terminals 22.

To the pad portion 21, a plurality of first wires 51 are bonded. Of the pad portion 21, a face facing the first side z1 and a face facing the second side z2 along the third direction z are defined as a main face 211 and a back face 212, respectively. The main face 211 has a bonded region 211a to which the plurality of first wires 51 are bonded. The bonded region 211a of the main face 211 can be subjected to plating. The plated layer formed by plating is formed of, for example, metal such as Ag. The plated layer enhances the bonding strength of the first wires 51 and also protects the second lead 2 from impact resulting from wire bonding of the first wires 51. The back face 212 is covered by the sealing resin 8.

When the semiconductor device 100 is mounted on the wiring substrate, the plurality of terminals 22 are bonded to the wiring substrate. The terminals 22 are coupled to an end part of the pad portion 21 toward the first side x1 along the first direction x. In the semiconductor device 100 according to the present disclosure, twelve terminals 22 are arrayed along the second direction y. Note that the shape, arrangement position, and number of terminals 22 are not limited to as described above.

The plurality of third leads 3 constitute conducting paths between the first and second semiconductor chips 41 and 42 and the wiring substrate on which the semiconductor device 100 is mounted. To the third leads 3, the wires 5 are bonded. The third leads 3 can include what is called a dummy lead to which none of the wires 5 is bonded. In the semiconductor device 100 according to the present disclosure, the third leads 3 include a dummy lead.

Of the third lead 3, a face facing the first side z1 and a face facing the second side z2 along the third direction z are defined as a main face 31 and a back face 32, respectively, and a face connecting together the main and back faces 31 and 32 is a side face 33. On the third lead 3, to the main face 31, the wires 5 are bonded. The main face 31 can be subjected to plating. The plated layer formed by plating is formed of, for example, metal such as Ag. The plated layer enhances the bonding strength of the wires 5 and also protects the third leads 3 from impact resulting from wire bonding of the wires 5. Note that only those third leads 3, to which the wires 5 are bonded can have a plated layer. At least part of the back face 32 or the side face 33 of the third lead 3 is exposed out of the sealing resin 8.

In the semiconductor device 100 according to the present disclosure, the plurality of third leads 3 include seven third leads 3a and 3f disposed in an end part of the semiconductor device 100 toward the second side x2 along the first direction x, displaced toward the first side y1 along the second direction y. The seven third leads 3a and 3f are arrayed along the second direction y between the terminals 12a and 12d along the second direction y.

In the semiconductor device 100 according to the present disclosure, the plurality of third leads 3 include seven third leads 3b disposed in an end part of the semiconductor device 100 toward the first side y1 along the second direction y, displaced toward the second side x2 along the first direction x. The seven third leads 3b are arrayed along the first direction x between the terminals 12b and 12d along the first direction x.

The plurality of third leads 3a, the plurality of third leads 3b, and the plurality third leads 3f include configurations that conduct to the second semiconductor chip 42 via the wires 5. The plurality of third leads 3a, the plurality of third leads 3b, and the plurality of third leads 3f include a dummy lead. Note that there is no limitation on which of the plurality of third leads 3a, the plurality of third leads 3b, and the plurality of third leads 3f conduct to the second semiconductor chip 42 or which of the electrodes, described later, of the second semiconductor chip 42 they conduct to. The numbers of third leads 3a, 3b, and 3f are not limited to as described above, and they do not necessarily include a dummy lead.

In the embodiment, the plurality of third leads 3 include one third lead 3c and one third lead 3e. The third lead 3c is disposed between the terminals 12a and 12e in an end part of the die pad 11 toward the second side x2 along the first direction x. The third lead 3e is disposed between the terminals 12c and 12e in an end part of the die pad 11 toward the second side y2 along the second direction y. The third leads 3c and 3e are what is called dummy leads. Note that the numbers of third leads 3c and 3e are not limited to as described above.

The parts of the leads 1 to 3 exposed out of the sealing resin 8 can have formed on them a plated layer containing, for example, Sn. Note that the material of the plated layer is not limited. This plated layer permits satisfactory soldering when the semiconductor device 100 is mounted on the surface of the wiring substrate by soldering and prevents corrosion of the leads 1 to 3 caused by soldering. Note that the shapes and arrangement of the leads 1 to 3 are not limited to as described above.

### First Semiconductor Chip 41 and Second Semiconductor Chip 42

The first semiconductor chip 41 is a GaN chip, and the second semiconductor chip 42 is a Si chip. A GaN chip is produced, for example, by forming a thin layer of GaN on a silicon substrate or a sapphire substrate and cutting it into chips. Note that a GaN chip 10 can be produced by cutting, for example, a GaN substrate into chips. A Si chip is produced by cutting, for example, a silicon substrate into chips.

The first semiconductor chip 41 includes an HEMT (high electron mobility transistor) using gallium nitride (GaN). The GaN-HEMT is used as a power device. That is, the first semiconductor chip 41 includes a GaN power device 6. The first semiconductor chip 41 is in the shape of a rectangle that is quadrate, as seen from the third direction z. Of the first semiconductor chip 41, a face facing the first side z1 along the third direction z is a chip main face 41a, and a face facing the second side z2 along the third direction z is a chip back face 41b.

In the semiconductor device 100 according to the present disclosure, a bonding member 43 is configured to be in contact with the chip back face 41b of the first semiconductor chip 41. The bonding member 43 conducts heat between the first semiconductor chip 41 and the first lead 1. Preferably, the bonding member 43 is made of a material with higher heat conductivity than the first lead 1. Examples of the material of the bonding member 43 include Ag paste. The bonding member 43 can be a bonding material such as solder or sintered silver. The bonding member 43 can be a conductive bonding material or an insulating bonding material.

The chip main face 41a of the first semiconductor chip 41 has a plurality of fir electrodes 411, a plurality of second electrodes 412, a plurality of third electrodes 413, and a plurality of fourth electrodes 414. As shown in FIGS. 2 and 3, the first semiconductor chip 41 is fitted to the die pad 11 of the first lead 1 via the bonding member 43. Specifically, the chip back face 41b of the first semiconductor chip 41 is bonded to the main face 111 of the die pad 11 via the bonding member 43.

As shown in FIG. 4, the first semiconductor chip 41 has the GaN power device 6 mounted on it. The first electrodes 411 are drain electrodes connected to wires leading to the drain of the GaN power device 6. The first electrodes 411 are arrayed along the second direction y in an end part of the chip main face 41a toward the first side x1 along the first direction x. The second electrodes 412 are gate electrodes connected to wires leading to the gate of the GaN power device 6. The second electrodes 412 are disposed in a corner part of the chip main face 41a toward the second side x2 along the first direction x, toward the first side y1 along the second direction y.

The third electrodes 413 are source electrodes connected to wires leading to the source of the GaN power device 6. The third electrodes 413 are arrayed along the second direction y in an end part of the chip main face 41a toward the second side x2 along the first direction x. The fourth electrodes 414 are Kelvin source terminals connected to wires serving as sense lines of the GaN power device 6. The fourth electrodes 414 are disposed in a corner part of the chip main face 41a toward the second side x2 along the first direction x, toward the first side y1 along the second direction y.

The semiconductor device 100 is used for switching a large electric current. Thus, the numbers of first and third electrodes 411 and 413 via which an input voltage VIN from outside is fed in and out are larger than that of second electrodes 412 via which a gate signal is fed in and that of fourth electrodes 414 used as the Kelvin source. Note that the chip main face 41a can have any other electrodes disposed on it. The layout of the arrangement of the electrodes 411 to 414 are not limited to as described above.

The second semiconductor chip 42 is configured to drive the first semiconductor chip 41. As shown in FIG. 4, the second semiconductor chip 42 generates a gate signal SGT based on an input signal SIN fed from outside and outputs it to the first semiconductor chip 41. The second semiconductor chip 42 includes a silicon (Si) semiconductor device. As shown in FIG. 4, the second semiconductor chip 42 includes a high-side switching device 426, a low-side switching device 427, two inverters 428 and 429 connected in series, and an inverter 420. The circuit configuration of the second semiconductor chip 42 will be described in detail later.

The second semiconductor chip 42 is in the shape of a rectangle that is quadrate as seen from the third direction z. Of the second semiconductor chip 42, a face facing the first side z1 and a face facing the second side z2 along the third direction z are defined as a chip main face 42a and a chip back face 42b, respectively.

As shown in FIGS. 2 and 3, the second semiconductor chip 42 is mounted on the die pad 11 of the first lead 1 via a bonding member 44. The bonding member 44 can have the same configuration as or a different configuration from the bonding member 43. The bonding member 44 is formed of a material that allows easy heat conduction between the second semiconductor chip 42 and the die pad 11 of the first lead 1.

The chip main face 42a of the second semiconductor chip 42 has disposed on it a plurality of first electrodes 421, a plurality of second electrodes 422, a plurality of third electrodes 423, a plurality of fourth electrodes 424, and a plurality of fifth electrodes 425. The first electrodes 421 receive an input signal SIN from outside. The first electrodes 421 are arrayed along the second direction y in an end part of the chip main face 42a toward the second side x2 along the first direction x, toward the first side y1 along the second direction y. The second electrodes 422 receive a constant voltage VREG from outside. The second electrodes 422 are arrayed along the first direction x in an end part of the chip main face 42a toward the first side y1 along the second direction y, toward the first side x1 along the first direction x.

The third electrodes 423 are connected to a connection point P1 to which the source of the high-side switching device 426 and the drain of the low-side switching device 427 are connected. The third electrodes 423 are arrayed along the second direction y in an end part of the chip main face 42a toward the first side x1 along the first direction x. The third electrodes 423 are gate signal output electrodes from which a gate signal SGT is output. The fourth electrodes 424 are connected to the Kelvin source of the first semiconductor chip 41. The fourth electrodes 424 are arrayed along the second direction y in an end part of the chip main face 42a toward the first side x1 along the first direction x. The fourth electrodes 424 are disposed further toward the second side y2 along the second direction y than the third electrodes 423.

The fifth electrodes 425 are connected to an external Kelvin source. The fifth electrodes 425 are arrayed along the second direction y in an end part of the chip main face 42a toward the second side x2 along the first direction x. The fifth electrodes 425 are disposed further toward the second side y2 along the second direction y than the first electrodes 421. Inside the second semiconductor chip 42, the fourth and fifth electrodes 424 and 425 are connected together. Note that the chip main face 42a can have any other electrodes disposed on it. The numbers and arrangement of different electrodes are not limited to as described above.

As shown in FIG. 2, the plurality of wires 5 together with the leads 1 to 3 constitute conducting paths for the first semiconductor chip 41 and the second semiconductor chip 42 to fulfill a predetermined function. The wires 5 can be formed of, for example, Cu, Au, Ag, Al, or any of alloys containing any of them, but this is not meant as any limitation. The plurality of wires 5 include a plurality of first wires 51, a plurality of second wires 52, a plurality of third wires 53, a plurality of fourth wires 54, a plurality of fifth wires 55, a plurality of sixth wires 56, and a plurality of seventh wires 57.

As shown in FIG. 2, the plurality of first wires 51 constitute conducting paths between the first semiconductor chip 41 and a plurality of second leads 2. The first wires 51 are bonded to, so as to conduct to, the first electrodes 411 of the first semiconductor chip 41 and the bonded region 211a of the second lead 2. This allows the first semiconductor chip 41 to output a voltage and a current to outside via the second lead 2 and the first wires 51.

The plurality of second wires 52 are bonded to, so as to conduct to, the second electrodes 412 of the first semiconductor chip 41 and the third electrodes 423 of the second semiconductor chip 42. Thus, the gate signal SGT output from the third electrodes 423 of the second semiconductor chip 42 is fed to the second electrodes 412 of the first semiconductor chip 41.

The plurality of third wires 53 are bonded to, so as to conduct to, the third electrodes 413 of the first semiconductor chip 41 and the bonded region 11a of the first lead 1. Thus, the input voltage VIN is fed to the first semiconductor chip 41 via the first lead 1 and the third wires 53.

The plurality of fourth wires 54 are bonded to, so as to conduct to, the fourth electrodes 414 of the first semiconductor chip 41 and the fourth electrodes 424 of the second semiconductor chip 42. Thus, the sense line of the GaN power device 6 is connected to the Kelvin source of the second semiconductor chip 42.

The plurality of fifth wires 55 are bonded to, so as to conduct to, the first electrodes 421 of the second semiconductor chip 42 and the third lead 3a. Thus, the input signal SIN is fed to the second semiconductor chip 42 via the third lead 3a and the fifth wires 55 (see FIG. 4).

The plurality of sixth wires 56 are bonded to, so as to conduct to, the second electrodes 422 of the second semiconductor chip 42 and the third leads 3b. Thus, the second semiconductor chip 42 is fed with the constant voltage VREG via the third lead 3b and the sixth wires 56 (see FIG. 4).

The plurality of seventh wires 57 are bonded to, so as to conduct to, the fifth electrodes 425 of the second semiconductor chip 42 and the third leads 3f. Thus, the second semiconductor chip 42 is connected to the Kelvin source via the third leads 3f and the seventh wires 57 (see FIG. 4).

The sealing resin 8 covers parts of the leads 1 to 3, the first and second semiconductor chips 41 and 42, and the plurality of wires 5. The sealing resin 8 is electrically insulating. The sealing resin 8 is formed of a material containing black epoxy resin, for example. Note that there is no particular limitation on the material of the sealing resin 8.

Next, the circuit configuration of the semiconductor device 100 will be described in detail. In the semiconductor device 100, an input signal SIN from outside is fed to the second semiconductor chip 42. The second semiconductor chip 42 adjusts the input signal SIN to generate a gate signal SGT. Then the gate signal SGT is fed to the first semiconductor chip 41. In the first semiconductor chip 41, the GaN power device 6 is controlled to be on or off by the gate signal SGT.

In the second semiconductor chip 42, the high-side switching device 426 and the low-side switching device 427 are both N-channel Si-MOSFETs. The source of the high-side switching device 426 and the drain of the low-side switching device 427 are connected together at the connection point P1. The source of the low-side switching device 427 is connected to the Kelvin source.

The inverters 428 and 429 connected in series are fed with the input signal SIN. The inverters 428 and 429 connected in series are driven by the constant voltage VREG with a constant voltage value. The output of the inverters 428 and 429 is fed to the gate of the high-side switching device 426.

Also the inverter 420 is fed with the outputs of the inverters 428 and 429, and its output is fed to the gate of the low-side switching device 427. The high-side and low-side switching devices 426 and 427 are driven so as to complementarily switch between on and off. Here, complementarily denotes operation in which, when one is on, the other is off. Note that, in complementary operation, while there is a dead time during which the high-side and low-side switching devices 426 and 427 are simultaneously off, they are controlled so as not to be simultaneously on.

The input signal SIN is a signal that switches between a high level and a low level. When the input signal SIN is at a high level, the GaN power device 6 is on. That is, the duty of the high level of the input signal SIN is the on-duty of the GaN power device 6.

The inverters 428 and 429 are driven by the constant voltage VREG. Thus, the output of the inverters 428 and 429 is, when it is at a high level, equal to the constant voltage VREG, and, when it is at a low level, “0.” That is, the gate voltage Vg2 of the high-side switching device 426 is 0 or VREG.

Let Vth be the threshold voltage of the N-channel MOS transistor (hereinafter, referred to as the NMOS transistor), then the drain-source voltage Vds of the NMOS transistor is typically Vds=Vg2−Vth. Since, in the second semiconductor chip 42 in the semiconductor device 100 according to the present disclosure, the gate voltage Vg2 of the high-side switching device 426 is the constant voltage VREG, the drain-source voltage Vds of the high-side switching device 426 is Vds=VREG−Vth.

The source of the high-side switching device 426 and the drain of the low-side switching device 427 are connected together at the connection point P1. That is, the voltage VS at the connection point P1 is a voltage equal to the drain-source voltage, that is, VS=VREG−Vth. In the second semiconductor chip 42, the voltage VS at the connection point P1 is output from the third electrodes 423 as the gate signal SGT.

As shown in FIGS. 2 and 4, the third electrodes 423 of the second semiconductor chip 42 and the second electrodes 412 of the first semiconductor chip 41 are connected via the second wires 52. As described above, in the first semiconductor chip 41, the second electrodes 412 are connected to the wires leading to the gate of the GaN power device 6. That is, the gate signal SGT generated by the second semiconductor chip 42 is fed to the gate of the GaN power device 6, and the GaN power device 6 is driven by the gate signal SGT.

In operation, the temperature of the semiconductor device 100 rises. In particular, the first semiconductor chip 41 is fed with a high voltage and a large current. Thus, the first semiconductor chip 41 generates a large amount of heat and becomes hot. This causes a rise in the temperature of the GaN power device 6.

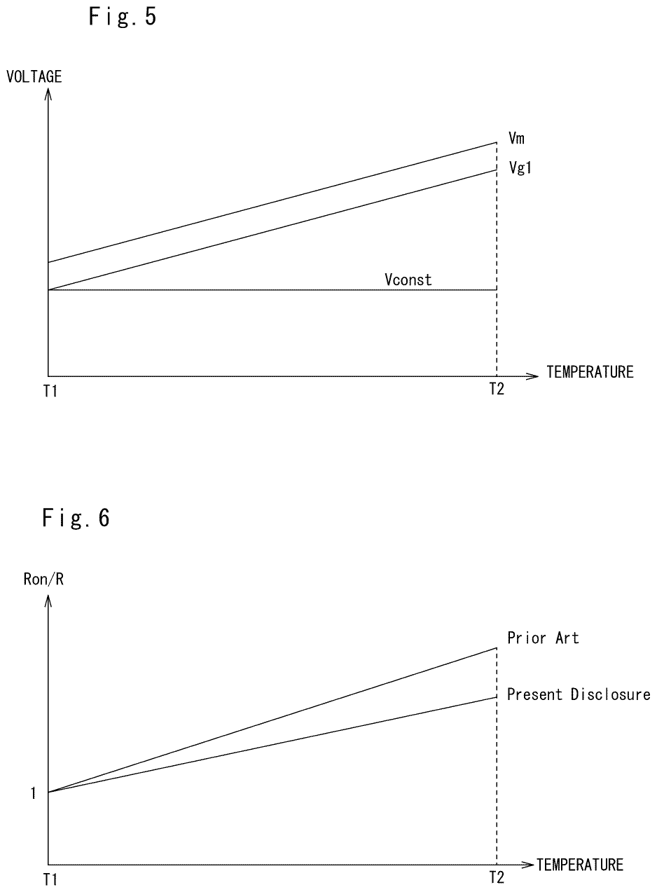

Now, the temperature characteristics of the GaN power device 6 will be described with reference to the relevant drawings. FIG. 5 is a graph showing, for the GaN power device 6, the temperature characteristics of the gate breakdown voltage and the gate voltage. FIG. 6 is a graph showing the temperature characteristics of the on-resistance Ron of the GaN power device 6. Note that the gate voltage Vg1 shown in FIG. 5 is the voltage observed when the gate signal SGT is at a high level.

In the graph in FIG. 5, the horizontal axis represents temperature and the vertical axis represents voltage. In the graph in FIG. 6, the horizontal axis represents temperature, and the vertical axis represents the ratio of the on-resistance Ron to the on-resistance R1 (Ron/R1). Note that temperatures T1 and T2 are the minimum and maximum values of the temperature assumed in the usage environment of the semiconductor device 100, and the temperature ranges in FIGS. 5 and 6 take temperature T1 as the minimum value and temperature T2 as the maximum value. FIG. 5 also indicates a constant gate voltage Vconst with a flat temperature response set as a gate voltage.

As shown in FIG. 5, the GaN power device 6 has what is called a positive temperature response such that, as temperature rises, the gate breakdown voltage Vm of the GaN power device 6 rises. That is, in the GaN power device 6, as its temperature rises, the gate breakdown voltage Vm rises. Typically, the gate voltage fed to the GaN power device 6 is set at a value lower than the gate breakdown voltage Vm. Thus, in conventional semiconductor devices, a voltage lower than the gate breakdown voltage Vm at temperature T1 set as the usage environment is set as the constant gate voltage Vconst. Regardless of the temperature of the GaN power device 6, the conventional semiconductor devices are controlled with the constant gate voltage Vconst.

When the GaN power device 6 is on, a current passes from its drain to its source. As shown in FIG. 6, the resistance between the drain and the source when the GaN power device 6 is on, that is, what is called the on-resistance Ron has a positive temperature response. That is, as the temperature of the GaN power device 6 rises, the on-resistance Ron rises, too. Note that the GaN power device 6 has characteristics such that, as the gate voltage Vg1 rises, the on-resistance Ron falls.

In the semiconductor device 100, the first and second semiconductor chips 41 a 42 are both mounted on the first lead 1, and the first lead 1 serves as a heat conducting portion. Typically, in the semiconductor device 100, the first semiconductor chip 41 generates more heat than the second semiconductor chip 42. Thus, in the semiconductor device 100, the heat in the first semiconductor chip 41 is conducted to the second semiconductor chip 42 via the first lead 1. Thus, the second semiconductor chip 42 is heated by the heat conducted from the first semiconductor chip 41 and its temperature rises.

The high-side switching device 426 in the second semiconductor chip 42 is a S MOSFET. The threshold voltage Vth of the Si-MOSFET has a negative temperature response. That is, the high-side switching device 426 configured as a Si-MOSFET has characteristics such that, as its temperature rises, the threshold voltage Vth falls.

In the semiconductor device 100, the gate voltage Vg1 that drives the GaN power device 6 is equal to the drain-source voltage Vds of the high-side switching device 426 in the second semiconductor chip 42. That is, the gate voltage Vg1 is given by formula 1 below.

$$V g 1 = V REG - V th \qquad ( formula 1 )$$

As described above, the constant voltage VREG is constant regardless of the ambient temperature, that is, it has a flat temperature response, and, as the temperature rises, the threshold voltage Vth falls. Thus, formula 1 shows that the GaN power device 6 has a positive temperature response such that, as the temperature rises, its gate voltage Vg1 rises (see FIG. 5). Note that the gate voltage Vg1 need be equal to or lower than the gate breakdown voltage Vm. Thus, the gate voltage Vg1 is adjusted to be equal to the gate voltage Vconst at temperature T1 and rises as the temperature rises.

At constant temperature, the on-resistance Ron of the GaN power device 6 is inversely proportional to the gate voltage Vg1. As shown in FIG. 5, in the semiconductor device 100, the gate voltage Vg1 of the GaN power device 6 rises as the temperature rises. Thus, at any temperature between temperatures T1 and T2, the on-resistance Ron of the GaN power device 6 is lower with the gate voltage Vg1 than with the gate voltage Vconst (see FIG. 6).

That is, with the semiconductor device 100 according to the present disclosure, is possible to improve the temperature characteristics of the on-resistance Ron of the GaN power device 6 and to reduce electric power consumption in the GaN power device 6 when the temperature rises. This allows power saving in the semiconductor device 100.

In the semiconductor device 100, the second semiconductor chip 42 is disposed close to the first semiconductor chip 41. This configuration eases heat conduction from the first semiconductor chip 41 to the second semiconductor chip 42. This promotes a temperature rise in the high-side switching device 426 and reduces the threshold voltage Vth. It is thus possible to increase the gate voltage Vg1 of the GaN power device 6. Thus, preferably, the second semiconductor chip 42 is disposed as close to the first semiconductor chip 41 as possible. Reducing the distance between the first and second semiconductor chips 41 and 42 helps reduce the distance of the second and fourth wires 52 and 54. It is thus possible to reduce the transmission loss of the gate signal SGT from the second semiconductor chip 42 to the first semiconductor chip 41.

### Modified Example

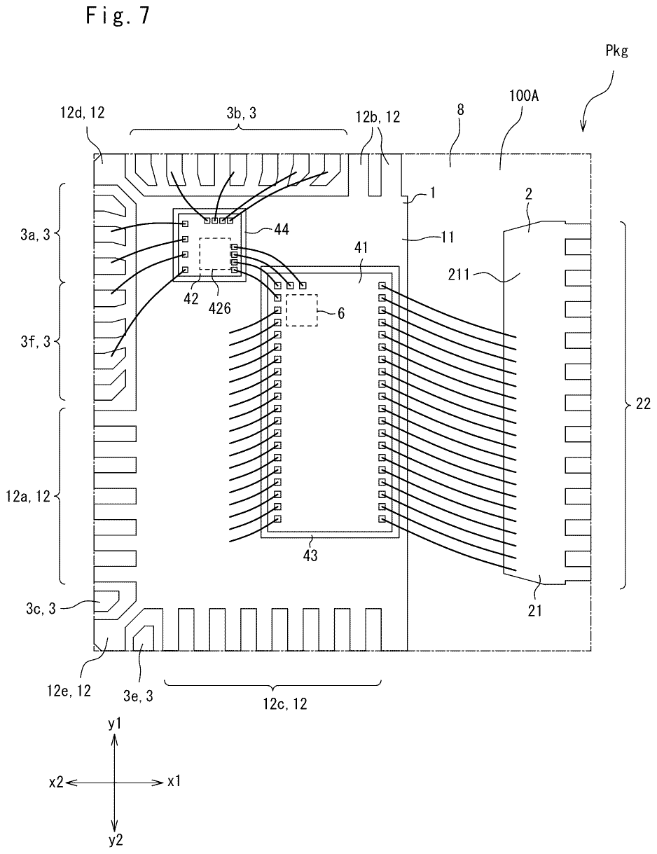

A modified example of the semiconductor device according to the present disclosure will be described with reference to the relevant drawing. FIG. 7 is a schematic layout diagram showing a first and a second semiconductor chip 41 and 42 in a semiconductor device 100A. FIG. 7 illustrates the positions, in the semiconductor device 100A, of a GaN power device 6 in the first semiconductor chip 41 and a high-side switching device 426 in the second semiconductor chip 42. The semiconductor device 100A has substantially the same configuration as the semiconductor device 100.

As shown in FIG. 7, the GaN power device 6 is disposed in a corner part of t first semiconductor chip 41 toward the first side x1 along the first direction x, toward the first side y1 along the second direction y. The high-side switching device 426 is disposed in a corner part of the second semiconductor chip 42 toward the second side x2 along the first direction x, toward the second side y2 along the second direction y.

With this configuration, it is possible to reduce the distance between the GaN power device 6 as a heat source and the high-side switching device 426 that generates the voltage VS of the connection point P1. This helps increase the voltage VS when the temperature of the semiconductor device 100A rises and helps improve the temperature characteristics of the on-resistance Ron of the GaN power device 6.

### Usage

An example of the use of the semiconductor device 100 according to the present disclosure will be described with reference to the relevant drawings.

### Switching Power Supply Device 200

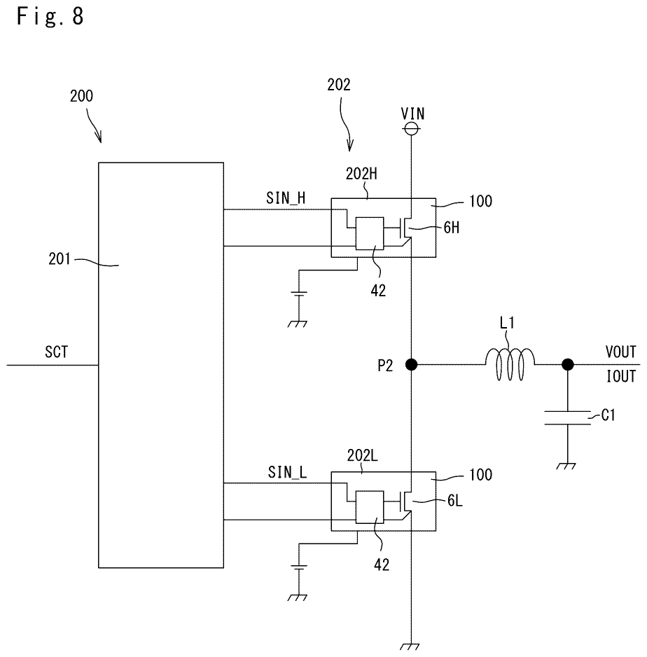

FIG. 8 is a schematic circuit diagram showing one example of the configuration a switching power supply device 200 using the semiconductor device 100. As shown in FIG. 8, the switching power supply device 200 includes a controller 201, a bridge circuit 202, an inductor L1, and a smoothing capacitor C1.

### Controller 201

The controller 201 is fed from outside with an instruction signal SCT that specifies at least either of an output voltage VOUT and an output current IOUT. Based on the instruction signal SCT, the controller 201 detects at least either of the output voltage VOUT and the output current IOUT and, based on the detection result, it outputs a high-side input signal SIN_H and a low-side input signal SIN_L to control a high-side switching portion 202H and a low-side switching portion 202L (both of them will be described later) in the bridge circuit 202.

### Bridge Circuit 202

The bridge circuit 202 is disposed between an input voltage VIN and a ground voltage and has a high-side and a low-side switching portions 202H and 202L each including the semiconductor device 100.

In the bridge circuit 202, the high-side and low-side switching portions 202H and 202L are connected in series between the input voltage VIN and the ground voltage. Thus, the drain of the GaN power device 6H in the high-side switching portion 202H is connected to the input voltage VIN and its source is connected to the drain of the GaN power device 6L in the low-side switching portion 202L at a connection point P2. The source of the GaN power device 6L in the low-side switching portion 202L is connected to the ground voltage.

The high-side switching portion 202H is fed from the controller 201 with the high-side input signal SIN_H that specifies when to switch the GaN power device 6H to a high level. The GaN power device 6H is fed at its gate with a gate signal SGT corresponding to the high-side input signal SIN_H and is controlled to be on or off according to the gate signal SGT. The high-side switching portion 202H is connected to the Kelvin source terminal of the controller 201.

Similarly, the low-side switching portion 202L is fed from the controller 201 with the low-side input signal SIN_L that specifies when to switch the GaN power device 6L to a high level. The GaN power device 6L is fed at its gate with a gate signal SGT corresponding to the low-side input signal SIN_L and is controlled to be on or off according to the gate signal SGT. The low-side switching portion 202L is connected to the Kelvin source terminal of the controller 201.

In the switching power supply device 200 configured as described above, the high-side GaN power device 6H and the low side GaN power device 6L are controlled so as to complementarily switch between on and off to output the output voltage VOUT and the output current IOUT. Using the GaN power devices 6H and 6L as the switching device makes it possible to output a high output voltage VOUT and a large output current IOUT.

With the semiconductor device 100, it is possible to keep low a rise in the on-resistance accompanying a rise in the temperature of the GaN power device 6. Improving the temperature characteristics of the on-resistance of the GaN power device 6 helps reduce electric power consumption in the GaN power device 6 and helps reduce power loss.

The switching power supply device 200 finds applications in vehicles such as automobiles, power supplies for industrial equipment, power conditioners connecting power generators and electricity storage systems, power supplies for AI servers, and the like. The switching power supply device 200 finds applications also in power adapters.

### Motor Device 400

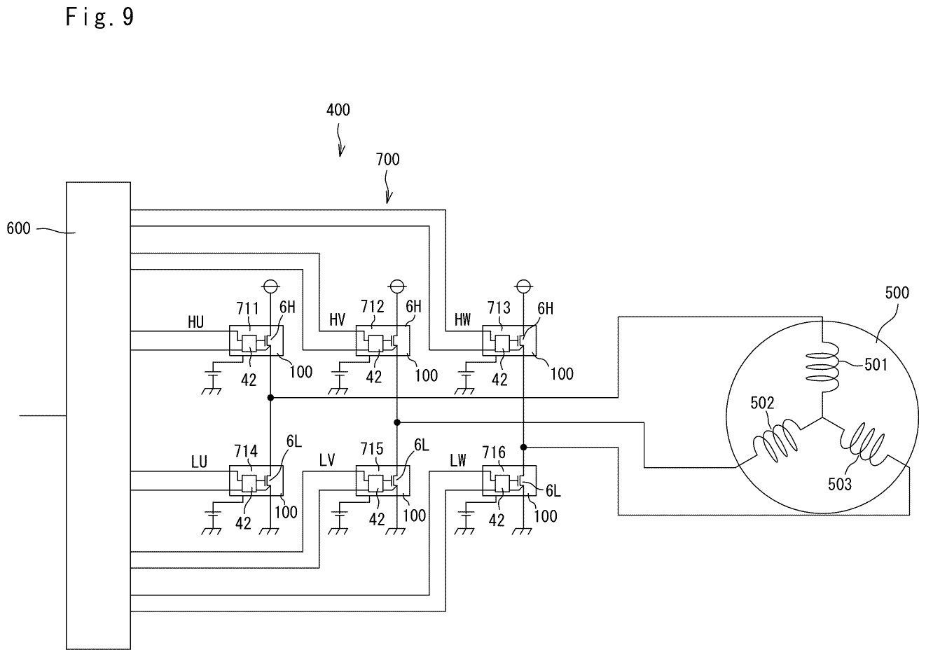

The semiconductor device 100 finds applications also in driving circuits for motor devices. FIG. 9 is a schematic configuration diagram of a motor device 400. The motor device 400 shown in FIG. 9 includes a motor 500, a controller 600, and a bridge circuit 700.

### Motor 500

The motor 500 is a permanent magnet synchronous motor. The motor 500 includes a U-phase coil 501, a V-phase coil 502, and a W-phase coil 503. Applying voltages of appropriate magnitudes with appropriate timing to the U-phase, V-phase, and W-phase coils 501, 502, and 503 to pass electric currents across them rotates the motor 500 at a predetermined rotation rate.

### Bridge Circuit 700

The bridge circuit 700 is a circuit that applies voltages to the U-phase, V-phase, and W-phase coils 501, 502, and 503 in the motor 500. In the motor device 400, the bridge circuit 700 is a three-phase full-bridge circuit.

The bridge circuit 700 includes a first, a second, a third, a fourth, a fifth, and sixth switching portion 711, 712, 713, 714, 715, and 716. In each of the switching portions 711, 712, 713, 714, 715, and 716, the semiconductor device 100 is used. The first and fourth switching portions 711 and 714 are connected in series to constitute a U-phase leg. Similarly, the second and fifth switching portions 712 and 715 are connected in series to constitute a V-phase leg. The third and sixth switching portions 713 and 716 are connected in series to constitute a W-phase leg.

The U-phase, V-phase, and W-phase legs all have a similar configuration to the bridge circuit shown in FIG. 8. That is, the U-phase, V-phase, and W-phase legs have a configuration where the GaN power device 6H and the GaN power device 6L are connected in series.

In the U-phase leg, the first switching portion 711 is fed with a U-phase high input signal HU, and the fourth switching portion 714 is fed with a U-phase low input signal LU. The GaN power devices 6H and 6L in the first and fourth switching portions 711 and 714 are controlled so as to be complementarily on and off by the U-phase high input signal HU and the U-phase low input signal LU, respectively. Then, the voltage at the connection point at which the GaN power devices 6H and 6L in the first and fourth switching portions 711 and 714 are connected together is supplied to the U-phase coil 501.

Similarly, in the V-phase leg, the second switching portion 712 is fed with a V-phase high input signal HV, and the fifth switching portion 715 is fed with a V-phase low input signal LV. The GaN power devices 6H and 6L in the second and fifth switching portions 712 and 715 are controlled so as to be complementarily on and off by the V-phase high input signal HV and the V-phase low input signal LV, respectively. Then, the voltage at the connection point at which the GaN power devices 6H and 6L in the second and fifth switching portions 712 and 715 are connected together is supplied to the V-phase coil 502.

Similarly, in the W-phase leg, the third switching portion 713 is fed with a W-phase high input signal HW, and the sixth switching portion 716 is fed with a W-phase low input signal LW. The GaN power devices 6H and 6L in the third and sixth switching portions 713 and 716 are controlled so as to be complementarily on and off by the W-phase high input signal HW and the W-phase low input signal LW, respectively. Then, the voltage at the connection point at which the GaN power devices 6H and 6L in the third and sixth switching portions 713 and 716 are connected together is supplied to the W-phase coil 503. As described above, the semiconductor device 100 can be employed in a driving circuit for a motor device.

With the semiconductor device 100, it is possible to keep low a rise in the on-resistance in response to a rise in the temperature of the GaN power device 6. It is also possible to effectively reduce power loss by employing the semiconductor device 100 in a driving circuit for a motor device with a configuration where so large a current as to drive the motor 500 passes. That is, the semiconductor device 100 can be particularly suitably used in driving circuits for devices that require a large current and a high voltage as motive power to drive mechanical device, such as motors and as power for servers.

### Notes

The above embodiment should be understood to be in every aspect illustrative and not restrictive. The scope of the present disclosure is set forth in the appended claims, and not in the above description of the embodiment. The scope of the present invention encompasses any modifications within a scope equivalent in significance to the claims.

### Overview

According to one aspect of the present disclosure, a semiconductor device (100, 100A) is configured to include a GaN power device (6) of which the gate breakdown voltage has a positive temperature response, a voltage supplying portion (426) that supplies, when the GaN power device (6) is turned on, a voltage (Vg1) at a high level with a positive temperature response to the gate of the GaN power device (6), and a heat conducting portion (1) that conducts heat between the GaN power device (6) and the voltage supplying portion (426). (A first configuration.)

According to another aspect of the present disclosure, a semiconductor device (100, 100A) is configured to include a GaN power device (6) of which the gate breakdown voltage has a positive temperature response and a voltage supplying portion (426) that supplies, when the GaN power device (6) is turned on, a voltage (Vg1) at a high level with a positive temperature respons e t o the gate of the GaN power device (6). The temperature of the voltage supplying portion (426) is configured to rise so as to follow a rise in the temperature of the GaN power device (6). (A second configuration.)

In the semiconductor device (100, 100A) according to the above first or second configuration, the voltage supplying portion can include a high-side switching device (426) and a low-side switching device (427). When the GaN power device (6) is turned on, a constant voltage (VREG) with a flat temperature response can be supplied to the gate of the high-side switching device (426), and a gate signal (SGT) corresponding to a voltage (VS) at a connection point (P1) between the high-side and low side switching devices (426, 427) can be supplied to the gate of the GaN power device. (A third configuration.)

In the semiconductor device (100, 100A) according to the above third configuration, the high-side and low-side switching devices (426, 427) can both be configured as N-channel MOS transistors. (A fourth configuration.)

In the semiconductor device (100, 100A) according to the above third or fourth configuration, the high-side switching device (426) can be fed with an input signal at its terminal opposite from the connection point. The semiconductor device can include a voltage stabilizing circuit (428, 429) that outputs an output voltage (Vg2) to the gate of the high-side switching device (426). The voltage stabilizing circuit (428, 429) can be fed with the input signal (SIN) and the constant voltage (VREG), and can output a high-level output voltage (Vg2) with a voltage value equal to the constant voltage (VREG). (A fifth configuration.)

In the semiconductor device (100, 100A) according to the above fifth configuration, the voltage stabilizing circuit (428, 429) can have an even number of inverter circuits (428, 429) connected in series. (A sixth configuration.)

The semiconductor device (100, 100A) according to any one of the above first sixth configurations can further include a Si chip (42) on which the voltage supplying portion (426) is mounted, a GaN chip (41) on which the GaN power device (6) is mounted, and a lead (1) that connects together the Si chip (42) and the GaN chip (41). (A seventh configuration.)

The semiconductor device (100A) according to the above fifth configuration can further include a Si chip (42) on which the voltage supplying portion (426) is mounted, a GaN chip (41) on which the GaN power device (6) is mounted, and a lead (1) that connects together the Si chip (42) and the GaN chip (41). In the Si chip (42), the high-side switching device (426) can be disposed closer toward the GaN chip (41) than either of the low-side switching device (427) and the voltage stabilizing circuit (428, 429). (An eighth configuration.)

In the semiconductor device (100A) according to the above seventh or eighth configuration, the lead (1) can have higher heat conductivity than either of the Si chip (42) and the GaN chip (41). (A ninth configuration.)

According to another aspect of the present disclosure, an LSI module (100, 100A) is configured to include the semiconductor device (100A) according to any one of the above seventh to ninth configurations. The Si chip (42), the GaN chip (41), and the lead (1) are configured to be sealed in resin to form a package. (A tenth configuration.)

According to another aspect of the present disclosure, a switching power supply device (200) is configured to include a bridge circuit (202) using the semiconductor device (100, 100A) according to any one of the above first to ninth configurations in a high-side switching portion (202H) and a low-side switching portion (202L). (An eleventh configuration.)

According to another aspect of the present disclosure, an LSI module (100, 100A) is configured to include the semiconductor device (100, 100A) according to any one of the above first to ninth configurations and a switching output stage (300) driven by the semiconductor device (100, 100A). (A twelfth configuration.)

According to another aspect of the present disclosure, a composite power supply device (200) is configured to include the semiconductor device (100, 100A) according to any one of the above first to ninth configurations and a plurality of output stages (401, 402, 403) that can be driven by the semiconductor device (100, 100A). At least one of the plurality of output stages (401, 402, 403) is configured to be driven by the semiconductor device (100, 100A). (A thirteenth configuration.)

### REFERENCE SIGNS LIST

100, 100A: semiconductor device, 1: first lead, 11: die pad, 11a: bonded region, 111: main face, 112: back face, 113: back face depressed part, 12, 12a, 12b, 12c, 12d, 12e: terminal, 2: second lead, 21: pad portion, 211: main face, 211a: bonded region, 212: back face, 22: terminal, 3, 3a, 3b, 3c, 3d, 3e, 3f: third lead, 31: main face, 32: back face, 33: side face, 41: first semiconductor chip, 41a: chip main face, 41b: chip back face, 411: first electrode, 412: second electrode, 413: third electrode, 414: fourth electrode, 42: second semiconductor chip, 42a: chip main face, 42b: chip back face, 420: inverter, 421: first electrode, 422: second electrode, 423: third electrode, 424: fourth electrode, 425: fifth electrode, 426: high-side switching device, 427: low-side switching device, 428, 429: inverter, 43: bonding member, 44: bonding member, 5: wire, 51: first wire, 52: second wire, 53: third wire, 54: fourth wire, 55: fifth wire, 56: sixth wire, 57: seventh wire, 6, 6H, 6L: GaN power device, 8: sealing resin, 200: switching power supply device, 201: controller, 202: bridge circuit, 202H: high-side switching portion, 202L: low-side switching portion, 400: motor device, 500: motor, 501: U-phase coil, 502: V-phase coil, 503: W-phase coil, 600: controller, 700: bridge circuit, 711: first switching portion, 712: second switching portion, 713: third switching portion, 714: fourth switching portion, 715: fifth switching portion, 716: sixth switching portion, C1: smoothing capacitor

What is claimed is:

1. A semiconductor device comprising:
a GaN power device of which a gate breakdown voltage has a positive temperature response;
a voltage supplying portion that, when the GaN power device is turned on, supplies a voltage at a high level with a positive temperature response to a gate of the GaN power device; and
a heat conducting portion that conducts heat between the GaN power device and the voltage supplying portion.

2. A semiconductor device comprising:
a GaN power device of which a gate breakdown voltage has a positive temperature response; and
a voltage supplying portion that supplies, when the GaN power device is turned on, a voltage at a high level with a positive temperature response to a gate of the GaN power device, wherein
a temperature of the voltage supplying portion rises so as to follow a rise in temperature of the GaN power device.

3. The semiconductor device according to claim 1, wherein
the voltage supplying portion includes a high-side switching device and a low-side switching device, and,
when the GaN power device is turned on, a constant voltage with a flat temperature response is supplied to a gate of the high-side switching device, and a gate signal corresponding to a voltage at a connection point between the high-side and low side switching devices is supplied to the gate of the GaN power device.

4. The semiconductor device according to claim 3, wherein
the high-side and low-side switching devices are both configured as N-channel MOS transistors.

5. The semiconductor device according to claim 3, wherein
the high-side switching device is fed with an input signal at a terminal thereof opposite from the connection point,
the semiconductor device includes a voltage stabilizing circuit that outputs an output voltage to the gate of the high-side switching device, and
the voltage stabilizing circuit is fed with the input signal and the constant voltage, and is operable to output a high-level output voltage with a voltage value equal to the constant voltage.

6. The semiconductor device according to claim 5, wherein
the voltage stabilizing circuit has an even number of inverter circuits connected in series.

7. The semiconductor device according to claim 3 further comprising:
a Si chip on which the voltage supplying portion is mounted;
a GaN chip on which the GaN power device is mounted; and
a lead that connects together the Si chip and the GaN chip.

8. The semiconductor device according to claim 5 further comprising:
a Si chip on which the voltage supplying portion is mounted;
a GaN chip on which the GaN power device is mounted; and
a lead that connects together the Si chip and the GaN chip, wherein,
in the Si chip, the high-side switching device is disposed closer toward the GaN chip than either of the low-side switching device and the voltage stabilizing circuit.

9. The semiconductor device according to claim 7, wherein
the lead has higher heat conductivity than either of the Si chip and the GaN chip.

10. An LSI module comprising:
the semiconductor device according to claim 7, wherein
the Si chip, the GaN chip, and the lead are sealed in resin to form a package.

11. A switching power supply device comprising:
a bridge circuit using the semiconductor device according to claim 1 in a high-side switch and a low-side switch.

12. The semiconductor device according to claim 2, wherein
the voltage supplying portion includes a high-side switching device and a low-side switching device, and,
when the GaN power device is turned on, a constant voltage with a flat temperature response is supplied to a gate of the high-side switching device, and a gate signal corresponding to a voltage at a connection point between the high-side and low side switching devices is supplied to the gate of the GaN power device.

13. The semiconductor device according to claim 12, wherein
the high-side and low-side switching devices are both configured as N-channel MOS transistors.

14. The semiconductor device according to claim 12, wherein
the high-side switching device is fed with an input signal at a terminal thereof opposite from the connection point,
the semiconductor device includes a voltage stabilizing circuit that outputs an output voltage to the gate of the high-side switching device, and
the voltage stabilizing circuit is fed with the input signal and the constant voltage, and is operable to output a high-level output voltage with a voltage value equal to the constant voltage.

15. The semiconductor device according to claim 14, wherein
the voltage stabilizing circuit has an even number of inverter circuits connected in series.

16. The semiconductor device according to claim 12 further comprising:
a Si chip on which the voltage supplying portion is mounted;
a GaN chip on which the GaN power device is mounted; and
a lead that connects together the Si chip and the GaN chip.

17. The semiconductor device according to claim 14, further comprising:
a Si chip on which the voltage supplying portion is mounted;
a GaN chip on which the GaN power device is mounted; and
a lead that connects together the Si chip and the GaN chip, wherein,
in the Si chip, the high-side switching device is disposed closer toward the GaN chip than either of the low-side switching device and the voltage stabilizing circuit.

18. The semiconductor device according to claim 16, wherein
the lead has higher heat conductivity than either of the Si chip and the GaN chip.

19. An LSI module comprising:
the semiconductor device according to claim 16, wherein
the Si chip, the GaN chip, and the lead are sealed in resin to form a package.

20. A switching power supply device comprising:
a bridge circuit using the semiconductor device according to claim 2 in a high-side switch and a low-side switch.
